(19) United States
(12) Patent Application Publication
(10) Pub. No.: US 2014/0125341 A1
(43) Pub. Date: May 8, 2014

(54) GRADIENT COIL MOUNTING UNIT AND MAGNETIC RESONANCE IMAGING APPARATUS HAVING THE SAME

(71) Applicant: Samsung Electronics Co., Ltd., Suwon-si (KR)

(72) Inventors: Jun-suk KWAK, Gwangju-si (KR); Seung-je CHOI, Suwon-si (KR); Sung-il KIM, Daejeon (KR)

(73) Assignee: Samsung Electronics Co., Ltd., Suwon-si (KR)

(21) Appl. No.: 13/895,438

(22) Filed: May 16, 2013

(30) Foreign Application Priority Data
Nov. 6, 2012 (KR) 10-2012-0125083

(51) Int. Cl. G01R 33/385; G01R 33/38

(52) U.S. Cl. CPC G01R 33/3858; G01R 33/3802
USPC 324/322; 29/745

(57) ABSTRACT

A gradient coil mounting unit for mounting a gradient coil module in a chamber of a magnetic resonance imaging (MRI) apparatus includes: vibration-proof pads provided on first and second edges of an inner surface of the chamber; and fixing taps provided on first and second edges of an outer surface of the gradient coil module. At least one vibration-proof pad has a shape that is complementary to a shape of a corresponding fixing tap.

### CROSS-REFERENCE TO RELATED PATENT APPLICATION

This application claims the priority from Korean Patent Application No. 10-2012-0125083, filed on Nov. 6, 2012, in the Korean Intellectual Property Office, the disclosure of which is incorporated herein in its entirety by reference.

### BACKGROUND

1. Field

Methods and apparatuses consistent with exemplary embodiments relate to a gradient coil mounting unit and a magnetic resonance imaging (MRI) apparatus having the same.

2. Description of the Related Art

An MRI apparatus is an imaging apparatus for medical diagnosis to see inner cross-sections of a human body. The MRI apparatus includes a main magnet that is used for applying a strong magnetic field towards the human body and a gradient coil that is used for providing information of a location of a magnetic field by applying a gradient magnetic field.

The gradient coil should be correctly mounted. Also, since vibrations and noises are generated during a high intensity operation of the main magnet when generating a magnetic field, there is a need to mount the gradient coil in the MRI apparatus to offset the vibrations.

### SUMMARY

Exemplary embodiments may address at least the above problems and/or disadvantages and other disadvantages not described above. Also, the exemplary embodiments are not required to overcome the disadvantages described above, and an exemplary embodiment may not overcome any of the problems described above.

One or more of exemplary embodiments provide a gradient coil mounting unit that reduces vibration and noise and mounts a gradient coil on a desired location, and an MRI apparatus having the gradient coil mounting unit.

According to an aspect of an exemplary embodiment, there is provided a gradient coil mounting unit for mounting a gradient coil module having a cylindrical in a cylindrical hollow of a chamber of a MRI apparatus, the gradient coil mounting unit including: a plurality of vibration-proof pads provided on both edges of an inner surface of the chamber; and a plurality of fixing taps provided on both edges of an outer surface of the gradient coil module, wherein at least one of the plurality of vibration-proof pads has a shape that is complementary to a shape of at least one of the plurality of fixing taps.

The at least one of the plurality of vibration-proof pads may have screw lines, and the at least one of the plurality of fixing taps may have screw lines complementary to the screw lines of the at least one of the plurality of vibration-proof pads, wherein the gradient coil module is mounted in the chamber by gearing the screw lines of the at least one of the plurality of vibration-proof pads with the screw lines of the at least one of the plurality of fixing taps while the gradient coil module rotates in the chamber.

Vibration-proof pads of the plurality of vibration-proof pads may be provided on at least three locations along an inner circumference of the chamber. At this point, fixing taps of the plurality of fixing taps may be provided discontinuously or consecutively along an outer circumference of the gradient coil module.

Vibration-proof pads of the plurality of vibration-proof pads may be consecutively provided along an inner circumference of the chamber. At this point, fixing taps of the plurality of fixing taps may be provided discontinuously or consecutively along an outer circumference of the gradient coil module.

The at least one of the plurality of vibration-proof pads has a gear shape in which a protrusion unit and a concave unit, which extend in a length direction of the chamber, are repeated, and the at least one of the plurality of fixing taps has a shape complementary to the gear shape of the at least one of the plurality of vibration-proof pads, wherein the c gradient coil module is mounted in the chamber by gearing the gear shape of the at least one of the plurality of vibration-proof pads with the gear shape of the at least one of the plurality of fixing taps while the gradient coil module moves straight ahead into the chamber.

The plurality of fixing taps may include first fixing taps provided on a front edge of the gradient coil module and second fixing taps provided on a rear edge of the gradient coil module viewed along a direction in which the gradient coil module is inserted into the chamber, wherein the first fixing taps are concavely formed on an outer surface of the gradient coil module and the second fixing taps are convexly formed on an outer surface of the gradient coil module. At this point, the plurality of vibration-proof pads may include first and second vibration-proof pads, wherein the first vibration-proof pads have thicknesses greater than that of the second vibration-proof pads so that the first vibration-proof pads are geared with the first fixing taps and the second vibration-proof pads are geared with the second fixing taps.

The plurality of fixing taps may include first fixing taps provided on a front edge of the gradient coil module and second fixing taps provided on a rear edge of the gradient coil module viewed along a direction in which the gradient coil module is inserted into the chamber, wherein the first and second fixing taps are concavely formed on an outer surface of the gradient coil module. At this point, the plurality of vibration-proof pads may include first vibration-proof pads provided on an edge of an inner surface of the chamber that are geared with the first fixing taps and second vibration-proof pads provided on another edge of the inner surface of the chamber to be geared with the second fixing taps, wherein the first and second vibration-proof pads have the same thickness. The second vibration-proof pads may be inserted into a gap between the chamber and the gradient coil module after the gradient coil module is inserted into the chamber.

The at least one of the plurality of fixing taps has a taper shape having a thickness which is gradually increased from a front side of the at least one of the plurality of fixing taps toward a rear side of the at least one of the plurality of fixing taps viewed along a direction in which the gradient coil module is inserted into the chamber. Or, the at least one of the plurality of fixing taps has a thickness which is constant from a front side of the at least one of the plurality of fixing taps to a rear side of the at least one of the plurality of fixing taps viewed along a direction in which the gradient coil module is inserted into the chamber.

The gradient coil mounting unit may be mounted so that the outer surface of the gradient coil module is separated from the inner surface of the chamber by the gradient coil mounting unit.

The gradient coil module may include a gradient coil and a resin mold in which the gradient coil is fixed. At this point, the fixing taps may be formed as one body with the resin mold or may be attached to the resin mold.

According to an aspect of an exemplary embodiment, there is provided an MRI apparatus including: a chamber having a cylindrical hollow and on which a main magnet is mounted; a cylindrical gradient coil module that is mounted in the cylindrical hollow of the chamber; and a gradient coil mounting unit that mounts the gradient coil module in the cylindrical hollow of the chamber, wherein the gradient coil mounting unit includes vibration-proof pads provided on both edges of an inner surface of the chamber and fixing taps provided on both edges of an outer surface of the gradient coil module, and the vibration-proof pads are shaped complementary to the fixing taps.

The gradient coil mounting unit according to the present invention and the MRI apparatus having the gradient coil mounting unit may reduce vibration and noise. Also, the gradient coil mounting unit may mount and fix the gradient coil on a correct location in the chamber.

### BRIEF DESCRIPTION OF THE DRAWINGS

The above and/or other aspects of exemplary embodiments will become more apparent by describing certain exemplary embodiments with reference to the accompanying drawings, in which:

FIG. 1 is a schematic horizontal cross-sectional view of an MRI apparatus according to an exemplary embodiment;

FIG. 2 is a schematic vertical cross-sectional view of the MRI apparatus of FIG. 1;

FIGS. 3A, 3B, and 3C are respectively a front view, a horizontal cross-sectional view, and a rear view of a gradient coil mounting unit, according to an exemplary embodiment;

FIGS. 4A, 4B, 4C, 4D, 4E, and 4F are cross-sectional views showing a process of mounting a gradient coil on the gradient coil mounting unit of FIGS. 3A through 3C;

FIGS. 5A, 5B, and 5C are respectively a front view, a horizontal cross-sectional view, and a rear view of a gradient coil mounting unit, according to an exemplary embodiment;

FIGS. 6A, 6B, 6C, 6D, 6E, 6F, 6G, 6H, and 6I are drawings showing a process of mounting a gradient coil module on the gradient coil mounting unit of FIGS. 5A through 5C, according to an exemplary embodiment;

FIGS. 7A, 7B, and 7C are respectively a front view, a horizontal cross-sectional view, and a rear view of a gradient coil mounting unit, according to an exemplary embodiment;

FIG. 8 is a cross-sectional view showing a process of mounting a gradient coil module on the gradient coil mounting unit of FIGS. 7A through 7C, according to an exemplary embodiment;

FIGS. 9A, 9B, and 9C are respectively a front view, a horizontal cross-sectional view, and a rear view of a gradient coil mounting unit, according to an exemplary embodiment;

FIG. 10 is a cross-sectional view showing a process of mounting a gradient coil module on the gradient coil mounting unit of FIGS. 9A through 9C, according to an exemplary embodiment;

FIGS. 11A, 11B, and 11C are respectively a front view, a horizontal cross-sectional view, and a rear view of a gradient coil mounting unit, according to an exemplary embodiment; and

FIGS. 12A, 12B, 12C, 12D, 12E, and 12F are drawings showing a process of mounting a gradient coil module on the gradient coil mounting unit of FIGS. 11A through 11C, according to an exemplary embodiment.

### DETAILED DESCRIPTION

Below, certain exemplary embodiments are described in greater detail with reference to the accompanying drawings.

In the following description, like reference numerals are used for the like elements, even in different drawings. The matters defined in the description, such as detailed construction and elements, are provided to assist in a comprehensive understanding of exemplary embodiments. However, exemplary embodiments can be carried out without those specifically defined matters. Also, well-known functions or constructions are not described in detail since that would obscure the description with unnecessary detail.

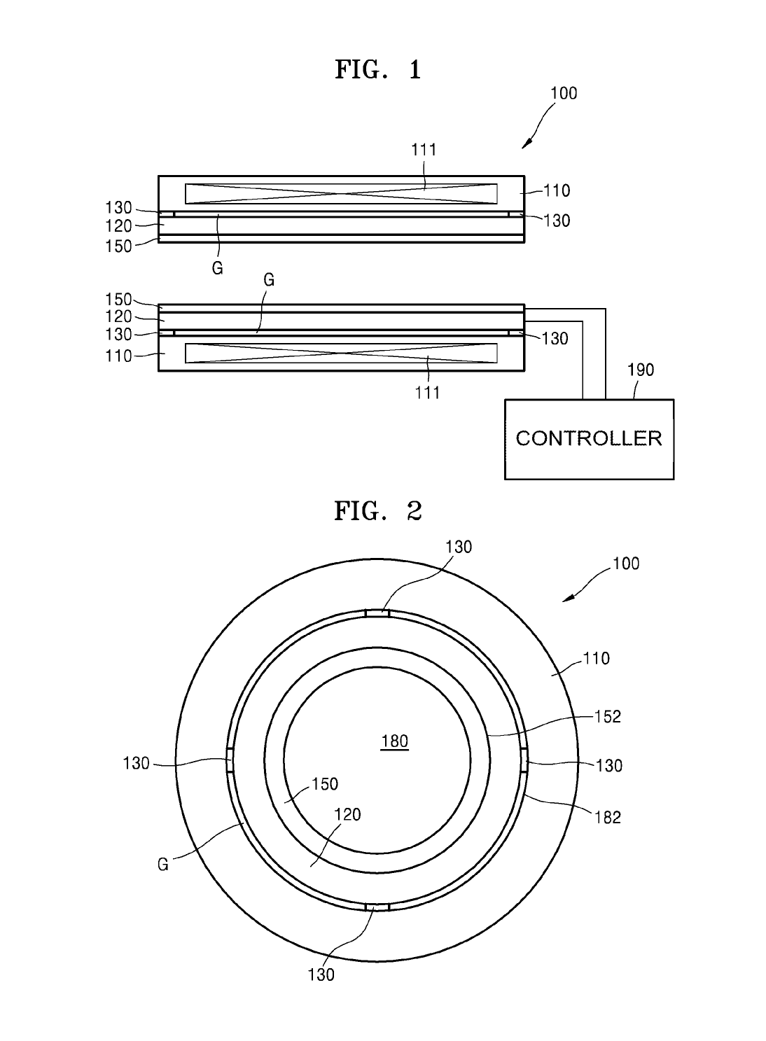

FIG. 1 is a schematic horizontal cross-sectional view of an MRI apparatus 100 according to an exemplary embodiment. FIG. 2 is a schematic vertical cross-sectional view of the MRI apparatus 100 of FIG. 1.

Referring to FIGS. 1 and 2, the MRI apparatus 100 includes a main magnet 111 mounted in a chamber 110. The main magnet 111 generates a main magnetic field that generates a magnetic resonance in atomic nuclei distributed in a human body, such as hydrogen, phosphor, and sodium, and may be a superconducting magnet or a permanent magnet. A superconducting magnet is used for generating a high intensity magnetic field greater than 0.5 Tesla. The main magnet 111 and the chamber 110 on which the main magnet 111 is mounted form a cylindrical structure having a cylindrical hollow space, i.e., a bore 180. When a superconducting magnet is used as the main magnet 111, the chamber 110 on which the main magnet 111 is mounted may be a cooling chamber that maintains a super low temperature.

A gradient coil module 120 is mounted on or proximate to an inner surface 182 of the chamber 110 to constitute a cylindrical magnetic structure together with the main magnet 111. The gradient coil module 120 generates a spatially linear gradient magnetic field to generate a magnetic resonance (MR) image. The gradient coil module 120 may include three gradient coils to respectively generate magnetic field gradients in x, y, and z directions. The gradient coil module 120 generates an MR image signal in a spatial frequency region, that is, in a k-region, by spatially controlling a rotation frequency of a magnetization vector when the magnetization vector rotates in a horizontal plane.

When the gradient coil module 120 is mounted on the cylindrical magnetic structure of the MRI apparatus 100, the gradient coil module 120 should be correctly mounted, and also, since vibration and noise are generated due to a high magnetic field (for example, a few Tesla) during an operation of the main magnet 111, the vibration needs to be reduced. Therefore, in the MRI apparatus 100 according to the current exemplary embodiment, the gradient coil module 120 is mounted while maintaining a separation distance equal to a predetermined gap G from an inner surface 182 of the chamber 110 by using a gradient coil mounting unit 130. The detailed structure of the gradient coil mounting unit 130 will be described below.

A high frequency module 150 is an apparatus that generates a high frequency magnetic field by using a Larmor frequency as a main frequency. The high frequency module 150 is mounted on an inner surface 152 of the gradient coil module 120, and thus, may form a portion of a cylindrical magnetic structure together with the main magnet 111 and the gradient coil module 120. The high frequency module 150 may include a transmit coil for resonating a magnetization vector and a receive coil for receiving an MR signal, or in some cases, may be used as a high frequency coil for transmission mode only or as a high frequency coil for receiving mode only.

The MRI apparatus 100 includes a controller 190 that drives and controls the main magnet 111, the gradient coil module 120, and the high frequency module 150. The main magnet 111, as described above, generates a main magnetic field that magnetizes atomic nuclei of an element that generates magnetic resonance, such as, hydrogen, phosphor, and sodium distributed in the human body. When the main magnet 111 is a superconducting magnet, the controller 190 may maintain and control a cooling state so that the main magnet 111 is maintained at a super conducting state. Also, the controller 190 generates a spatially linear gradient magnetic field by driving the gradient coil module 120. Also, the controller 190 applies a high frequency current of a Larmor frequency band to the high frequency module 150 to generate a nuclear magnetic resonance (NMR) in a magnetized vector, the magnetized vector having been magnetized by a main magnetic field of the main magnet 111, and thus, generates a magnetization vector along a horizontal plane. Once the magnetized vector is generated along the horizontal plane, the magnetized vector rotates with a Larmor frequency on the horizontal plane and generates a driving force signal in the high frequency module 150 (or an additional receive-only high frequency coil) by the Faraday law. After amplifying the driving force signal by using a high frequency amplifier, when the driving force signal is demodulated to a sine wave of the Larmor frequency, an MR signal of a base band may be obtained. After quantizing the MR signal of a base band, the quantized magnetic resonance signal is transmitted to a computer. When the quantized MR signal is processed, an MR image may be obtained.

Next, the gradient coil mounting unit 130 that is employed to the MRI apparatus 100 according to the current exemplary embodiment will be described.

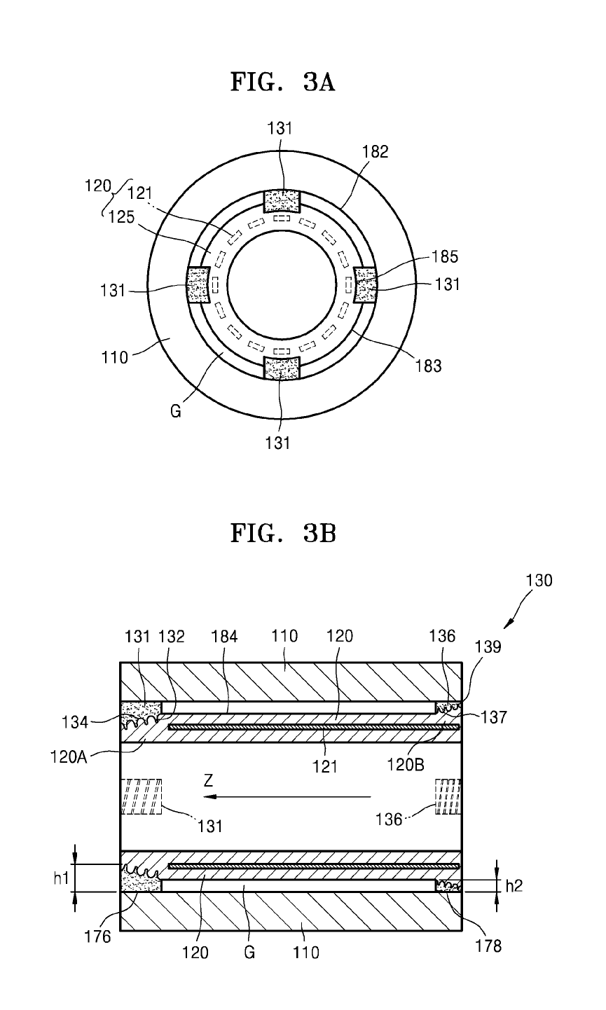

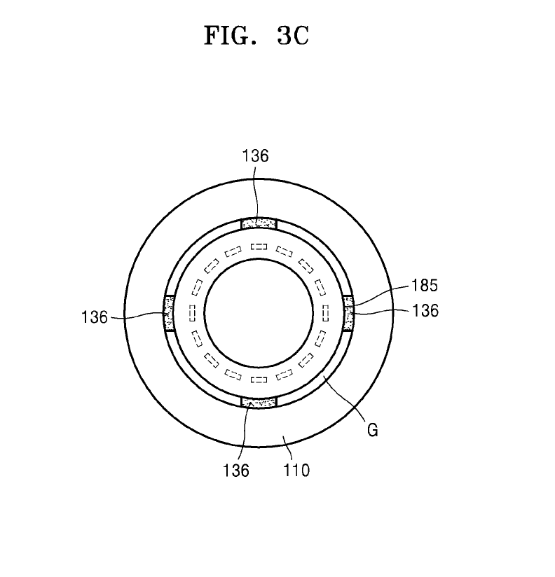

FIGS. 3A, 3B, and 3C are respectively a front view, a horizontal cross-sectional view, and a rear view of the gradient coil mounting unit 130 that is employed to the MRI apparatus 100 of FIG. 1, according to an exemplary embodiment.

Referring to FIGS. 3A through 3C, the gradient coil mounting unit 130 according to the current exemplary embodiment is a unit for mounting the cylindrical gradient coil module 120 in the chamber 110, and includes first and second vibration-proof pads 131 and 136 provided on first and second sides, i.e., front and rear sides 176, 178 of an inner surface 182 of the chamber 110. The first vibration-proof pads 131 are provided on a front side 176 of the chamber 110 based on a direction Z in which the gradient coil module 120 is inserted into the chamber 110, and the second vibration-proof pads 136 are provided on a rear side 178 of the chamber 110. As described below, the first and second vibration-proof pads 131 and 136 may be formed of a material having elasticity such as rubber or having a good damping performance to reduce vibration and noise generated from the gradient coil module 120.

The gradient coil module 120 may have a cylindrical structure in which a gradient coil 121 is fixed by a resin mold 125. Viewed along a direction Z in which the gradient coil module 120 is inserted into the chamber 110, first fixing taps 134 are provided on a front edge 120A of the gradient coil module 120 and second fixing taps 139 are provided on a rear edge 120B of the gradient coil module 120. The first and second fixing taps 134 and 139 may be formed as one body with the resin mold 125 of the gradient coil module 120. Of course, the current exemplary embodiment does not exclude a case in which the first and second fixing taps 134 and 139 are separately manufactured and are attached to outer surfaces 183 of the resin mold 125 of the gradient coil module 120.

The first and second vibration-proof pads 131 and 136 may have inner surfaces 185 including screw lines 132 and the first and second fixing taps 134 and 139 may have complementary screw lines to the screw lines of the first and second vibration-proof pads 131 and 136, and thus, the gradient coil module 120 may be mounted by gearing the screw lines of the first and second vibration-proof pads 131 and 136 with the screw lines of the first and second fixing taps 134 and 139 while the gradient coil module 120 is rotated in the chamber 110.

The first fixing taps 134 are concavely shaped with respect to an outer surface 184 of the gradient coil module 120, i.e., the first fixing taps 134 include oval-shaped members extending toward an inner surface 182 of the chamber 110 and narrow gaps extending therebetween. The second fixing taps 139 are convexly formed on an outer surface 184 of the gradient coil module 120, i.e., the second fixing tabs 139 include protrusion-shaped members or teeth extending toward an inner surface 182 of the chamber 110 and oval-shaped gaps extending therebetween. In this case, the screw lines of the first vibration-proof pads 131 are convexly formed having protrusion members matching the narrow gaps extending between the oval-shaped members of the first fixing taps 134, and the screw lines of the second vibration-proof pads 136 are concavely formed having oval-shaped members matching the oval-shaped gaps extending between the protrusion members of the second fixing taps 139. The thickness h1 of the first vibration-proof pads 131, with respect to a direction perpendicular to the direction Z, is greater than the thickness h2 of the second vibration-proof pads 136, and the first vibration-proof pads 131 may be geared with the first fixing taps 134 and the second vibration-proof pads 136 may be geared with the second fixing taps 139. Since the screw lines of the first vibration-proof pads 131 are formed having a thickness equivalent to a concave depth of the oval-shaped members of the first fixing taps 134 and/or the screw lines of the second vibration-proof pads 136 are formed having a thickness equivalent to a convex depth of the protrusion members of the second fixing taps 139, the substantial reduction of vibration may be achieved.

Furthermore, each of the first and second fixing taps 134 and 139 has a tapered shape in which their respective thicknesses are gradually increased starting from a front side of the at least one of the plurality of fixing taps toward a rear side of the at least one of the plurality of fixing taps viewed along a direction (Z direction) in which the gradient coil module 120 is inserted into the chamber 110, and each of the first and second vibration-proof pads 131 and 136 has a tapered shape complementary to the first and second fixing taps 134 and 139, and thus, the gradient coil module 120 is smoothly inserted into the chamber 110. In the current exemplary embodiment, a case in which the first and second fixing taps 134 and 139 have a tapered shape is described, but is not limited thereto. That is, the first and second fixing taps 134 and 139 may have a thickness which is constant from a front side of the at least one of the plurality of fixing taps to a rear side of the at least one of the plurality of fixing taps viewed along a direction (Z direction) in which the gradient coil module 120 is inserted into the chamber 110.

Each of the first and second vibration-proof pads 131 and 136 is provided at at least three locations along an inner circumference of the chamber 110 in order to stably mount the gradient coil module 120. As an example, as depicted in FIG. 3A, the first vibration-proof pads 131 may be provided equidistally, with equal gaps, at four locations along the inner circumference of the chamber 110, and, as depicted in FIG. 3C, the second vibration-proof pads 136 may be provided equidistally at four locations along an inner circumference of the chamber 110. The first and second fixing taps 134 and 139 may include match marks for mounting the gradient coil module 120, and thus, the gradient coil module 120 may be mounted on a correct location of the first and second vibration-proof pads 131 and 136 by aligning the match marks with the first and second vibration-proof pads 131 and 136.

Of course, each of the first and second fixing taps 134 and 139 may be provided discontinuously, with the equal gaps or at different spacings, along an outer circumference of the gradient coil module 120. In this case, each of the first and second fixing taps 134 and 139 may be provided at at least three locations along the outer circumference of the gradient coil module 120 in order to stably mount the gradient coil module 120. The number of the first and second fixing taps 134 and 139 and the number of the first and second vibration-proof pads 131 and 136 may be the same or different.

As described above, according to the current exemplary embodiment, the outer surface of the gradient coil module 120 may be separated by a predetermined gap G from the inner surface 182 of the chamber, and the gradient coil module 120 is supported by the first and second vibration-proof pads 131 and 136. In this way, since the gradient coil module 120 maintains a separation distance by using the first and second vibration-proof pads 131 and 136 on the inner surface of the chamber 110, vibration and noise may be effectively reduced. Furthermore, the first vibration-proof pads 131 are formed having a thickness equivalent to the concave depth of the first fixing taps 134, and thus, the reduction of vibration may further be improved.

Next, a process of mounting the gradient coil module 120 by using the gradient coil mounting unit 130 according to the current exemplary embodiment will be described.

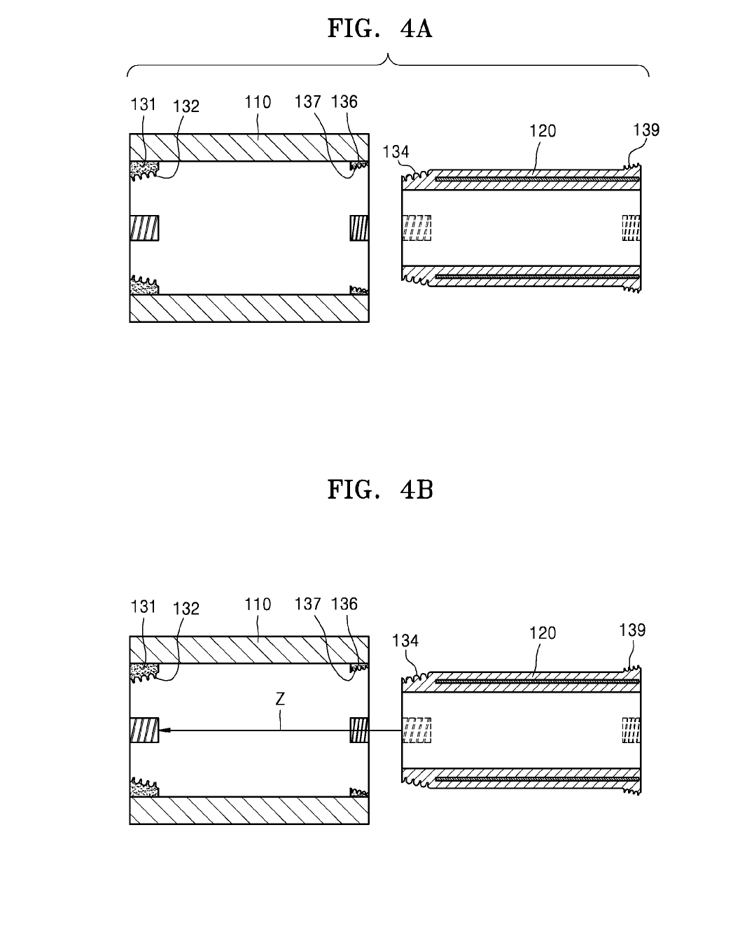

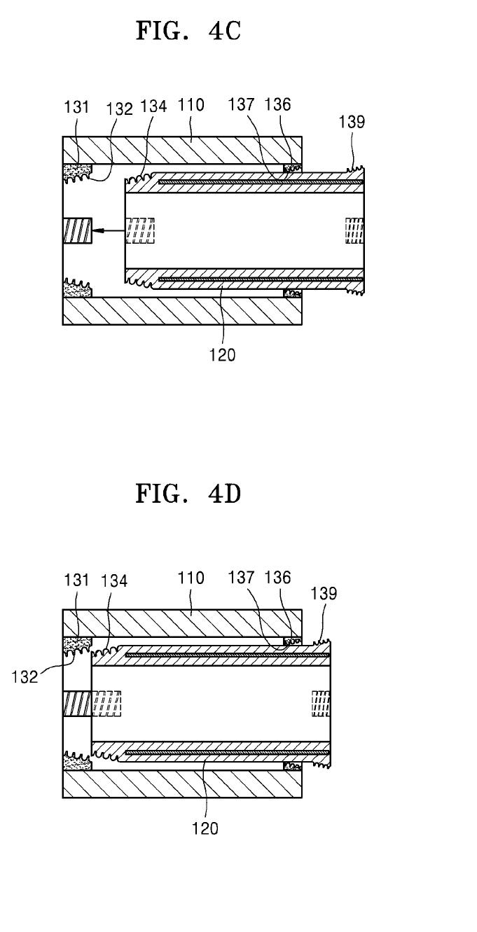

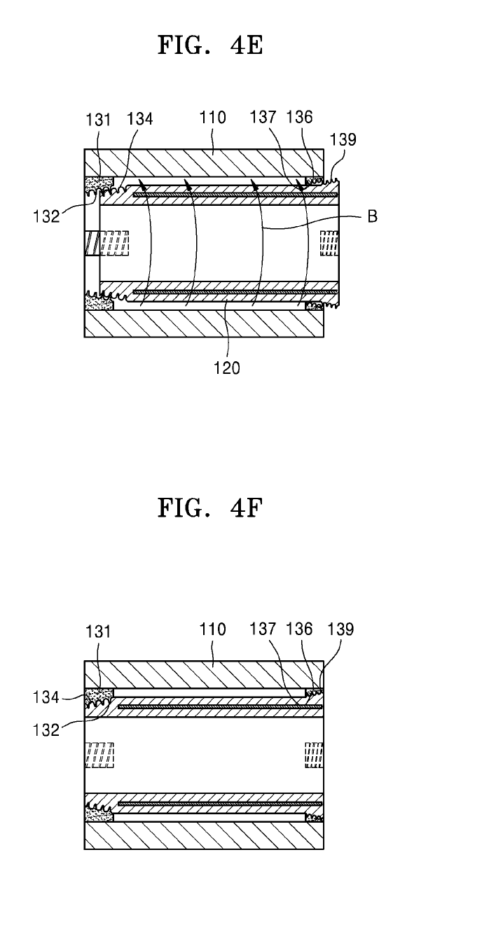

FIGS. 4A, 4B, 4C, 4D, 4E, and 4F are cross-sectional views showing a process of mounting the gradient coil module 120 on the MRI apparatus 100 having the gradient coil mounting unit 130 of FIGS. 3A through 3C.

FIG. 4A shows the gradient coil module 120 which is not mounted in the chamber 110. As depicted in FIG. 4B, the gradient coil module 120 is inserted (direction Z) into the chamber 110 with the first fixing taps 134 as a front side. Due to the sizes and shapes of the first and second fixing taps 134 and 139 and the first and second vibration-proof pads 131 and 136, as depicted in FIGS. 4C and 4D, the first fixing taps 134 and the gradient coil module 120 may be inserted into the chamber 110 without any resistance until the first fixing taps 134 meet the first vibration-proof pads 131. Next, as depicted in FIG. 4E, after meeting the first fixing taps 134 with the first vibration-proof pads 131, the gradient coil module 120 is rotated (direction B) in a screwlike manner so that the first fixing taps 134 are geared with the first vibration-proof pads 131 and the second fixing taps 139 are geared with the second vibration-proof pads 136. As a result, as depicted in FIG. 4F, the gradient coil module 120 is mounted in the chamber 110.

The gradient coil module 120 generates a magnetic field gradient for taking an MR image, and thus the gradient coil module 120 must be mounted on a desired location in a cylindrical magnetic structure of the MRI apparatus 100. The gradient coil module 120 according to the current exemplary embodiment is mounted by a screwlike manner, and the front and the rear of the gradient coil module 120 may be readily controlled and thicknesses of the first and second vibration-proof pads 131 and 136 are controlled. Therefore, a mounting height of the gradient coil module 120 may be correctly controlled.

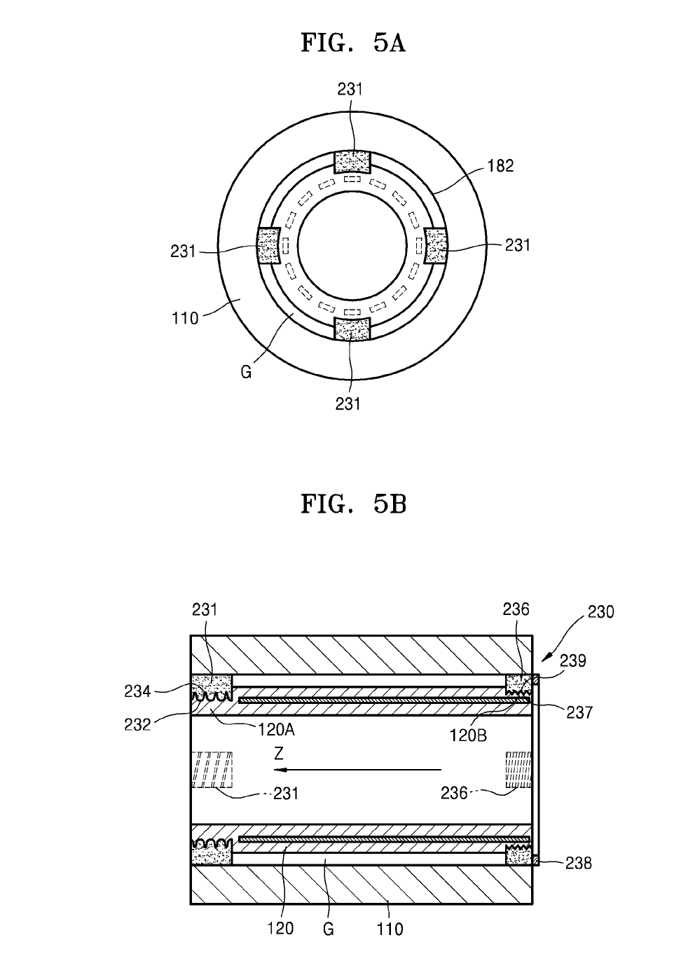

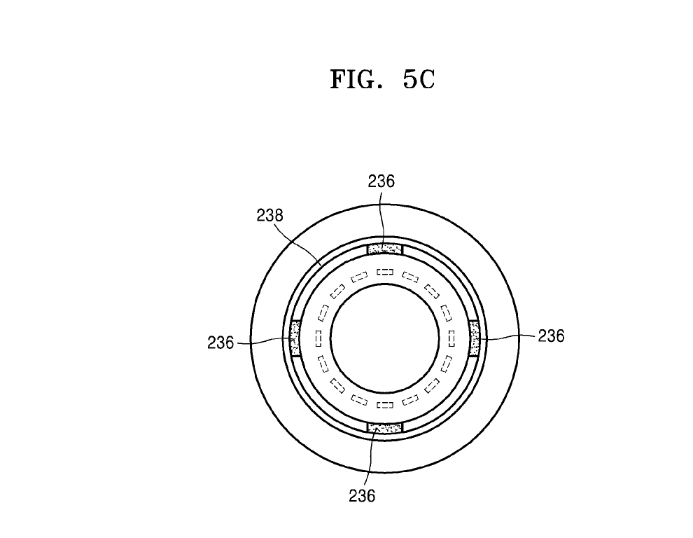

FIGS. 5A, 5B, and 5C are respectively a front view, a horizontal cross-sectional view, and a rear view of a gradient coil mounting unit 230 employed to the MRI apparatus 100 of FIG. 1, according to an exemplary embodiment.

Referring to FIGS. 5A through 5C, the gradient coil mounting unit 230 according to the current exemplary embodiment is a unit for mounting the cylindrical gradient coil module 120 in the chamber 110, and includes first and second vibration-proof pads 231 and 236 provided on both edges of the inner surface of the chamber 110. The first vibration-proof pads 231 are provided on a front edge of the chamber 110 viewed along a direction Z in which the gradient coil module 120 is inserted into the chamber 110, and the second vibration-proof pads 236 are provided on a rear edge of the chamber 110. Also, viewed along a direction Z in which the gradient coil module 120 is inserted into the chamber 110, first fixing taps 234 are provided on a front edge 120A of the gradient coil module 120, and a second fixing taps 239 are provided on a rear edge 120B of the gradient coil module 120. An outer surface of the gradient coil module 120 is supported by first and second vibration-proof pads 231 and 236 while maintaining a separation distance equal to a predetermined gap G from an inner surface 182 of the chamber 110.

The first and second fixing taps 234 and 239 may have screw lines in a concave shape that are concavely shaped with respect to an outer surface of the gradient coil module 120. The first and second vibration-proof pads 231 and 236 may have screw lines 232 shaped complementary to the screw lines of the first and second fixing taps 234 and 239. Since the first and second fixing taps 234 and 239 are concavely formed with respect to the outer surface of the gradient coil module 120, the first and second vibration-proof pads 231 and 236 are formed having a thickness equivalent to the concave depth of the first and second fixing taps 234 and 239, and thus, the reduction of vibration may be improved. The elements of the gradient coil mounting unit 230 according to the current exemplary are substantially the same as those of the gradient coil mounting unit 130 described in an exemplary embodiment of FIGS. 3 and 4, and thus the repeated detailed description of those elements is omitted. For example, similarly to an exemplary embodiment of FIGS. 3 and 4 described above, the first and second vibration-proof pads 231 and 236 may be formed from an elastic material or a material having a good damping performance. The first and second fixing taps 234 and 239 may be formed as one body with the resin mold 125 of the gradient coil module 120 or may be combined after being separately formed. Each of the first and second vibration-proof pads 231 and 236 is provided at at least three locations along an inner circumference of the chamber 110 in order to stably mount the gradient coil module 120. Each of the first and second fixing taps 234 and 239 may be consecutively provided along an outer circumference of the gradient coil module 120. In some cases, each of the first and second vibration-proof pads 231 and 236 may be consecutively provided along an inner circumference of the chamber 110, and each of the first and second fixing taps 234 and 239 may be provided at at least three locations along the inner circumference of the chamber 110.

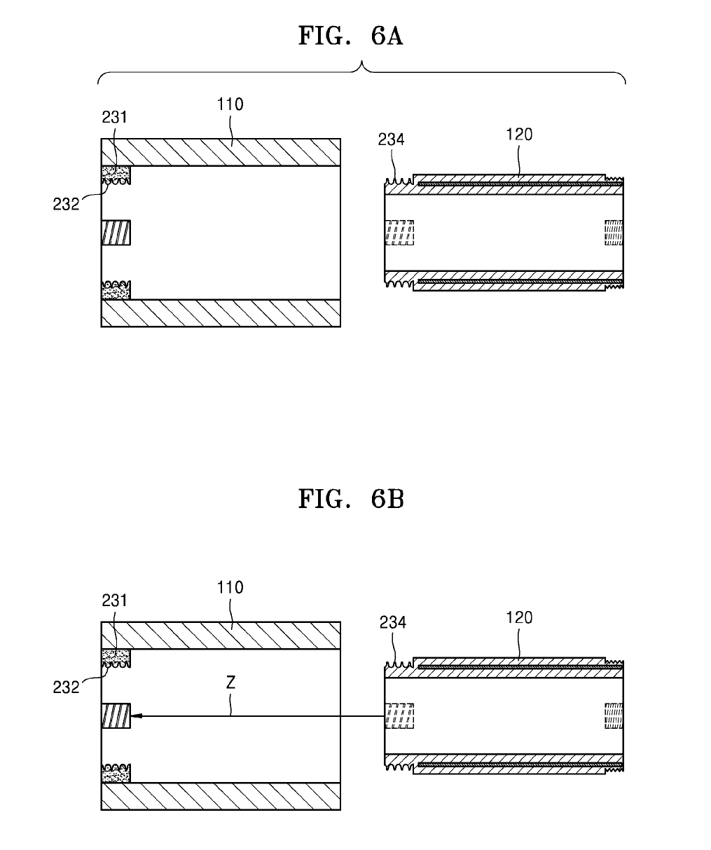

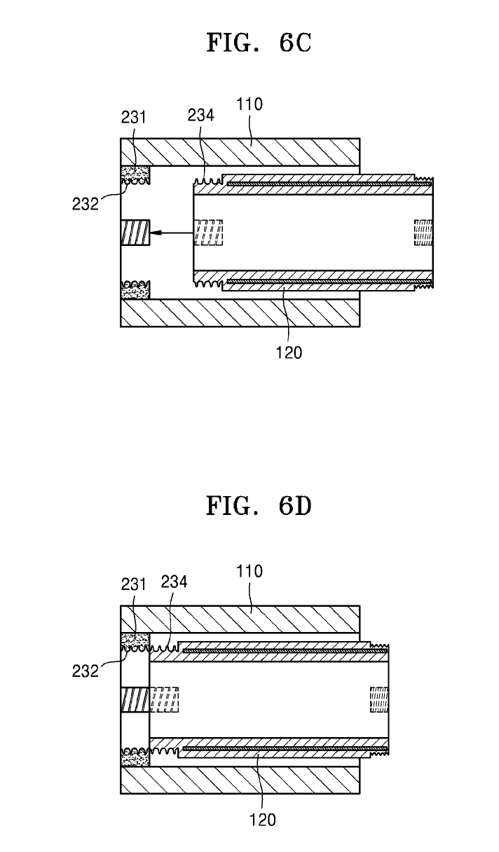

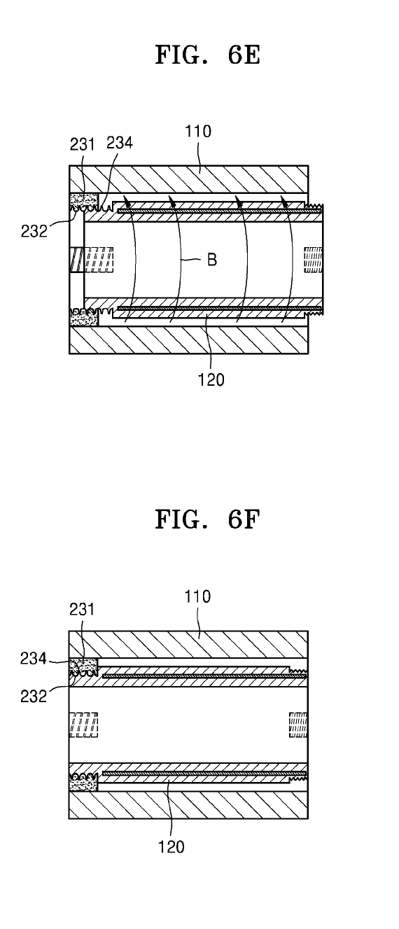

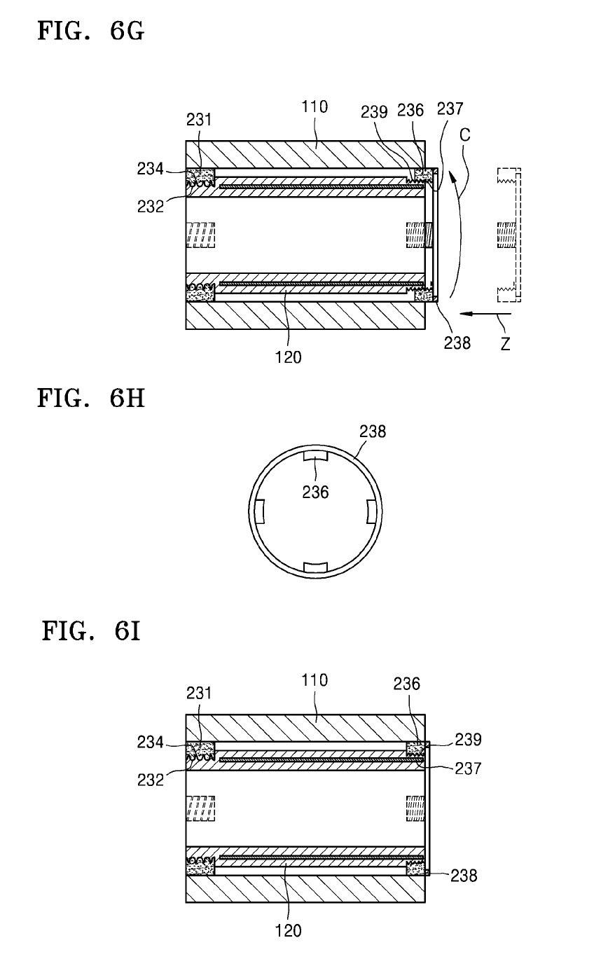

Since the second vibration-proof pads 236 have a shape complementary to the second fixing taps 239 that are concave with respect to an outer side surface of the gradient coil module 120, as described below, the second vibration-proof pads 236 may be inserted in a screwlike manner in the gap G between the chamber 110 and the gradient coil module 120 after the gradient coil module 120 is inserted into the chamber 110. The second vibration-proof pads 236 may be inserted in a supported state by a supporting ring 238 (refer to FIG. 6H). Of course, the second vibration-proof pads 236 may be individually inserted without the supporting ring 238.

FIGS. 6A, 6B, 6C, 6D, 6E, 6D, 6F, 6G, 6H, and 6I are drawings showing a process of mounting a gradient coil module 120 on the MRI apparatus 100 having the gradient coil mounting unit 230 of FIGS. 5A through 5C, according to an exemplary embodiment.

FIG. 6A shows the gradient coil module 120 which is not mounted in the chamber 110. Referring to FIGS. 6A and 6G, in the gradient coil mounting unit 230 according to the current exemplary embodiment, the second vibration-proof pads 236 are not attached to the inner surface of the chamber 110 before the gradient coil module 120 is mounted in the chamber 110.

As depicted in FIGS. 6B through 6D, when the gradient coil module 120 is inserted (direction Z) into the chamber 110 with the first fixing taps 234 of the gradient coil module 120 as a front side, the gradient coil module 120 may be smoothly inserted into the chamber 110 until the first fixing taps 234 meet the first vibration-proof pads 231. Next, as depicted in FIG. 6E, after the first fixing taps 234 meet the first vibration-proof pads 231, the gradient coil module 120 is rotated (direction B) in a screwlike manner so that, as depicted in FIG. 6F, the first fixing taps 234 of the gradient coil module 120 are geared with the first vibration-proof pads 231 of the chamber 110. Next, as depicted in FIG. 6G, the second vibration-proof pads 236 that are separately provided are inserted between the chamber 110 and the gradient coil module 120 in a screwlike manner. Once completed, as depicted in FIG. 6I, the gradient coil module 120 is mounted in the chamber 110.

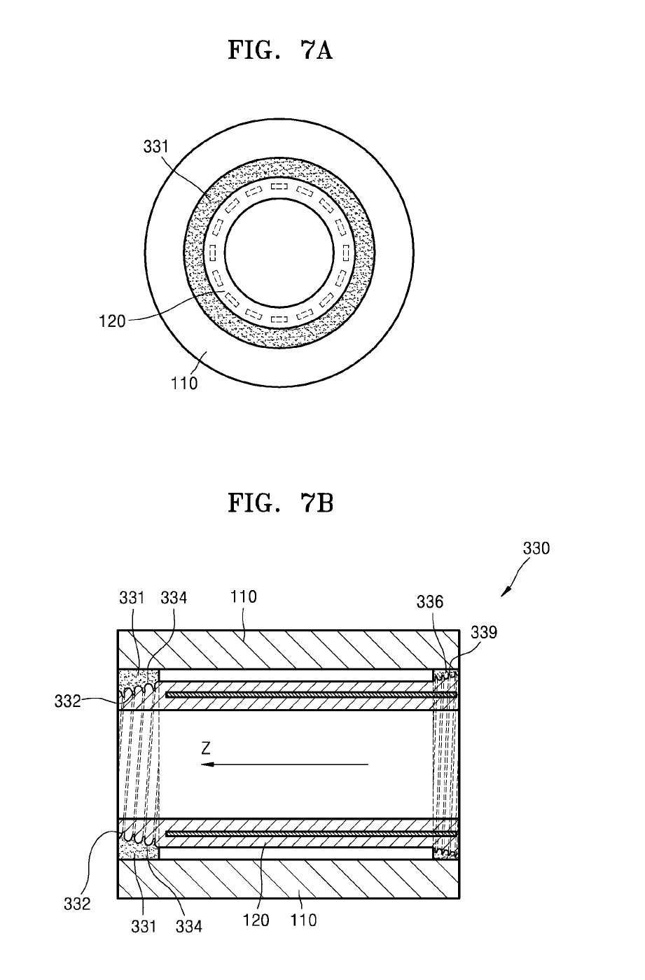

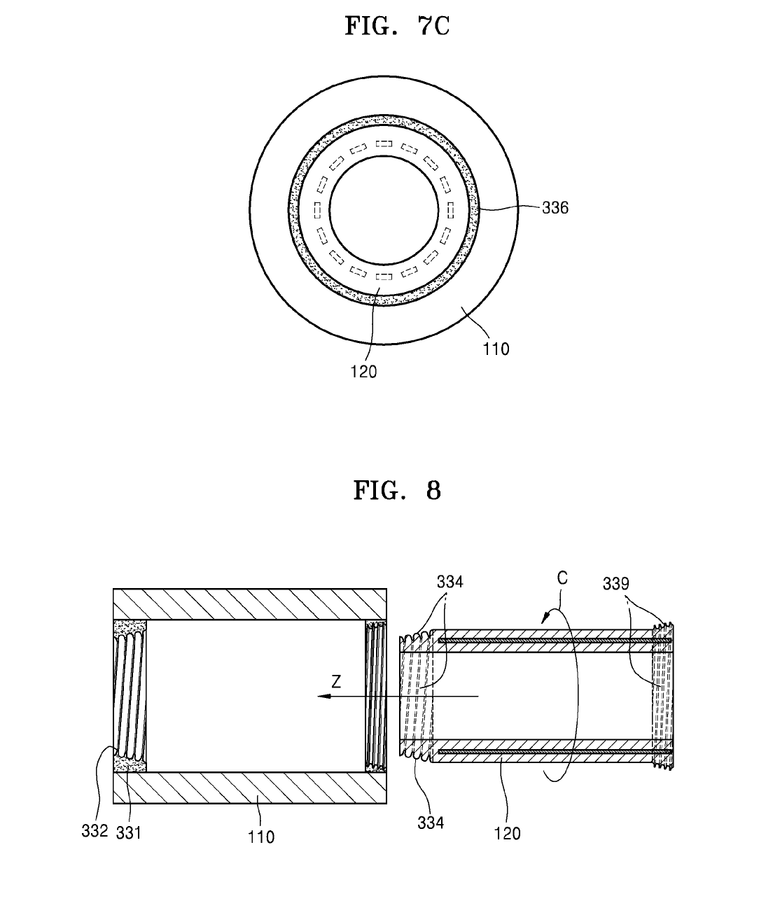

FIGS. 7A, 7B, and 7C are respectively a front view, a horizontal cross-sectional view, and a rear view of a gradient coil mounting unit 330 employed to the MRI apparatus 100 of FIG. 1, according to an exemplary embodiment.

Referring to FIGS. 7A through 7C, the gradient coil mounting unit 330 according to the current exemplary embodiment is a unit for mounting the cylindrical gradient coil module 120 in the chamber 110 and includes first and second vibration-proof pads 331 and 336 provided on both edges of an inner surface of the chamber 110. Also, first and second fixing taps 334 and 339 are provided on both edges of an outer surface of the gradient coil module 120. The first and second vibration-proof pads 331 and 336 according to the current exemplary embodiment are contiguously formed along an inner circumference of the chamber 110. In the gradient coil mounting unit 330 according to the current exemplary embodiment, the elements of the gradient coil mounting unit 330 are substantially the same as those of the gradient coil mounting unit 130, and thus, the detailed description thereof will not be repeated.

FIG. 8 is a cross-sectional view showing a process of mounting the gradient coil module 120 on the MRI apparatus 100 having the gradient coil mounting unit 330 of FIGS. 7A through 7C, according to an exemplary embodiment. Referring to FIG. 8, the gradient coil module 120 is combined with the chamber 110 by inserting (direction Z) and rotating (direction C) the gradient coil module 120 in a screwlike manner, which is substantially the same as the mounting method described with reference to FIGS. 4A through 4F.

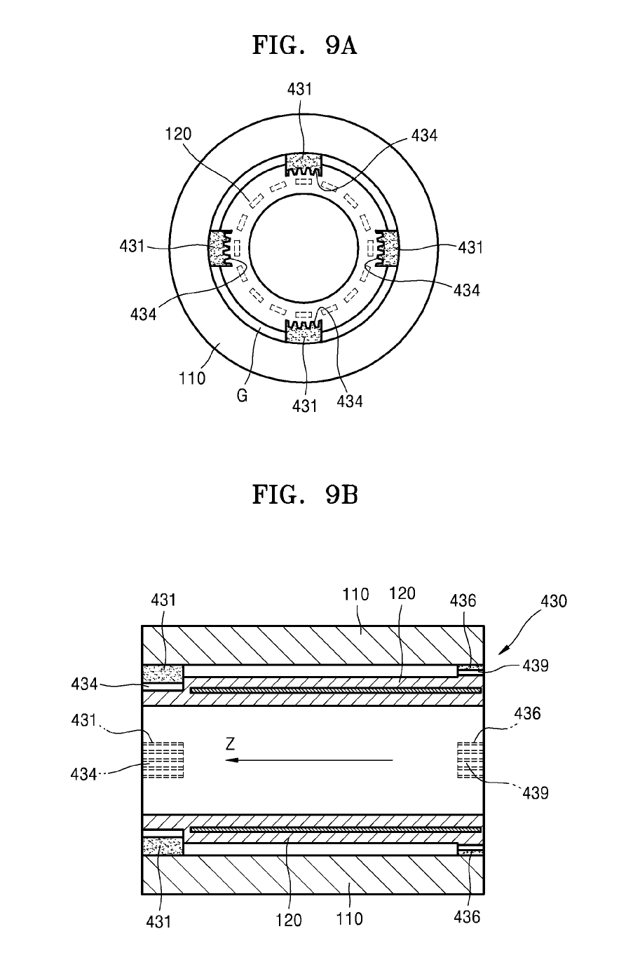

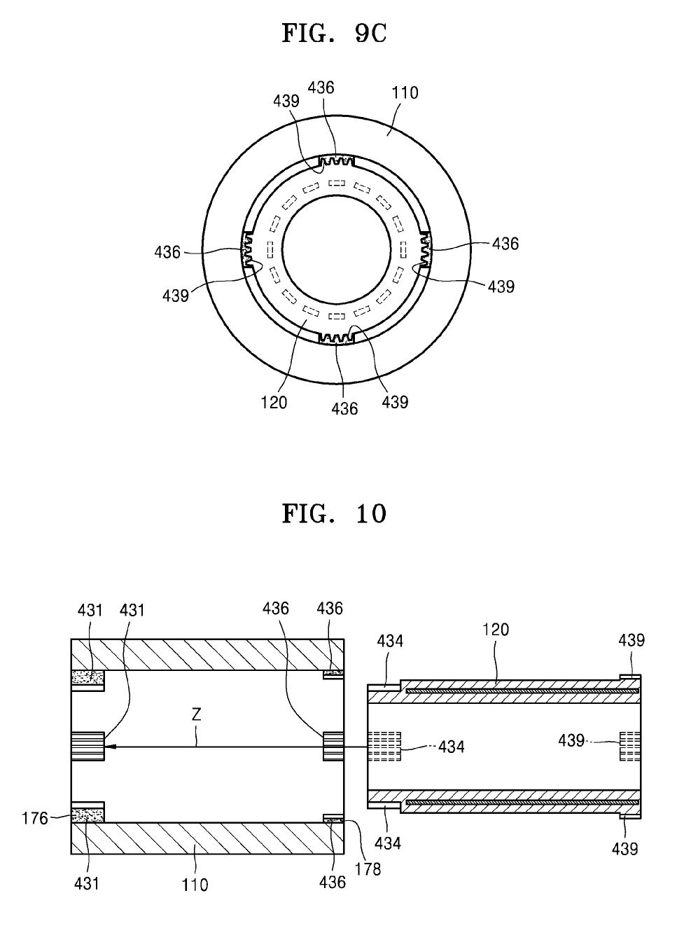

FIGS. 9A, 9B, and 9C are respectively a front view, a horizontal cross-sectional view, and a rear view of a gradient coil mounting unit 430 employed to the MRI apparatus 100 of FIG. 1, according to an exemplary embodiment.

Referring to FIGS. 9A through 9C, the gradient coil mounting unit 430 according to the current exemplary embodiment is a unit for mounting the cylindrical gradient coil module 120 in the chamber 110, and includes first and second vibration-proof pads 431 and 436. Also, first and second fixing taps 434 and 439 are provided on both edges of an outer surface of the gradient coil module 120.

The first and second vibration-proof pads 431 and 436 have gear shapes, respectively, in which a protrusion member and a concave member, which extend along a length direction (direction Z) of the chamber 110, are alternatively repeated, and the first and second fixing taps 434 and 439 have shapes complementary to the gear shapes, respectively, of the first and second vibration-proof pads 431 and 436.

The first fixing taps 434 may be concavely shaped on an outer surface of the gradient coil module 120, and the second fixing taps 439 may be convexly formed on the outer surface of the gradient coil module 120. In this case, the first vibration-proof pads 431 are formed to have a thickness greater than that of the second vibration-proof pads 436, and thus, the first vibration-proof pads 431 may be geared with the first fixing taps 434 and the second vibration-proof pads 436 may be geared with the second fixing taps 439.

Each of the first and second vibration-proof pads 431 and 436 may be formed at at least three locations along an inner circumference of the chamber 110 in order to stably mount the gradient coil module 120 in the chamber 110, and the first and second fixing taps 434 and 439 may be formed at at least three locations along an outer circumference of the gradient coil module 120. For example, as depicted in FIG. 9A, the first vibration-proof pads 431 may be formed at four locations along an inner circumference of the chamber 110, and the first fixing taps 434 may be formed at four locations along an outer circumference of the gradient coil module 120. Also, as depicted in FIG. 9C, the second vibration-proof pads 436 may be provided at four locations along an inner circumference of the chamber 110, and the second fixing taps 439 may be provided at four locations along an outer circumference of the gradient coil module 120.

In the current exemplary embodiment, each of the first and second fixing taps 434 and 439 has a constant height in a direction Z. However, the present exemplary embodiment is not limited thereto. Similar to the gradient coil mounting unit 130 described above, the gear shape of each of the first and second fixing taps 434 and 439 may have a tapered shape in which the thickness is gradually increased from the front edge towards the rear edge viewed along a direction Z in which the gradient coil module 120 is inserted into the chamber 110, and each of the first and second vibration-proof pads 431 and 436 may have a tapered shape complementary to the gear shape of the first and second fixing taps 434 and 439, and thus, the gradient coil module 120 may be smoothly inserted into the chamber 110.

FIG. 10 is a cross-sectional view showing a process of mounting the gradient coil module 120 on the MRI apparatus 100 having the gradient coil mounting unit 430 of FIGS. 9A through 9C. Referring to FIG. 10, in the gradient coil mounting unit 430 according to the current exemplary embodiment has the first and second vibration-proof pads 431 and 436 and the first and second fixing taps 434 and 439, all having a gear shape. Thus, the gradient coil module 120 may be mounted in the chamber 110 by pushing the gradient coil module 120 in a direction Z without having to rotate the gradient coil module 120 in the chamber 110.

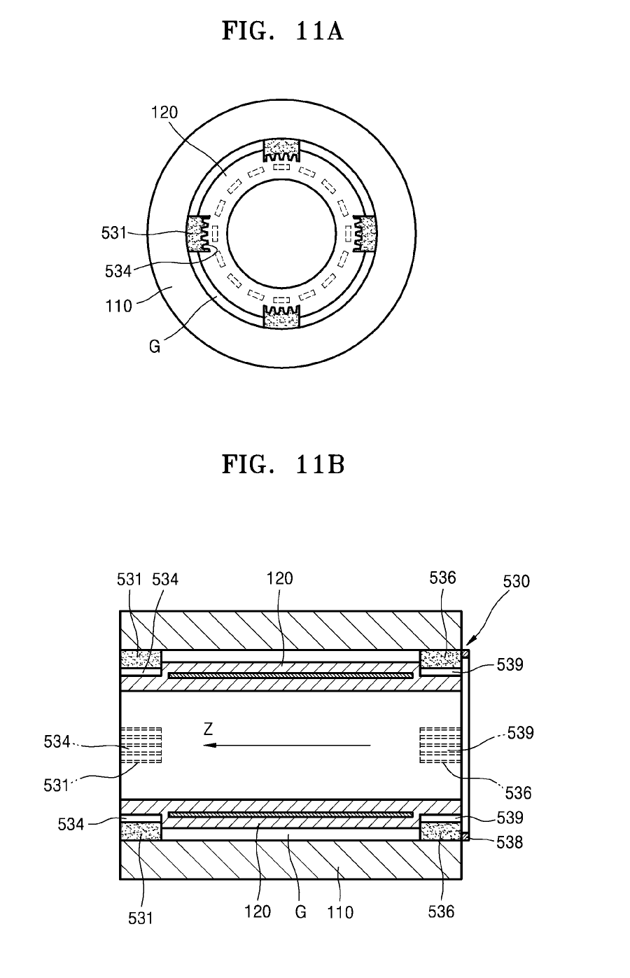

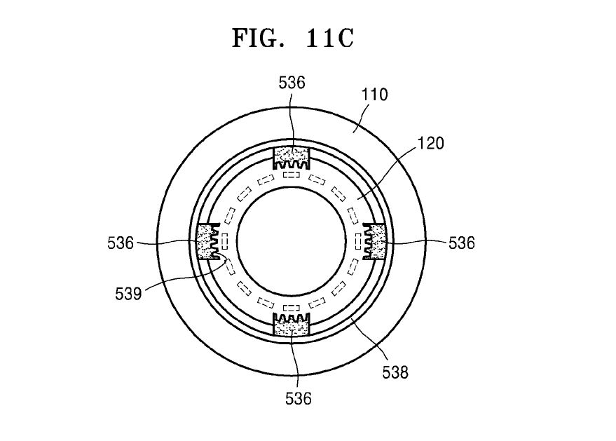

FIGS. 11A, 11B, and 11C are respectively a front view, a horizontal cross-sectional view, and a rear view of a gradient coil mounting unit 530 employed to the MRI apparatus 100 of FIG. 1, according to an exemplary embodiment.

Referring to FIGS. 11A through 11C, the gradient coil mounting unit 530 according to the current exemplary embodiment is a unit for mounting the cylindrical gradient coil module 120 in the chamber 110, and includes first and second vibration-proof pads 531 and 536 provided on both edges of an inner surface of the chamber 110. Also, first and second fixing taps 534 and 539 are provided on both edges of an outer surface of the gradient coil module 120.

The first and second fixing taps 534 and 539 each have a gear shape that is concave with respect to an outer surface of the gradient coil module 120. The first and second vibration-proof pads 531 and 536 each have a gear shape complementary to the gear shape of the first and second fixing taps 534 and 539, respectively. Since the first and second fixing taps 534 and 539 are concavely formed with respect to the outer surface of the gradient coil module 120, the first and second vibration-proof pads 531 and 536 are formed having a thickness amounting to the concaved depth of the first and second fixing taps 534 and 539, and thus, the reduction of vibration may be improved. Since the second vibration-proof pads 536 have a shape complementary to the second fixing taps 539 that are concavely formed with respect to the outer surface of the gradient coil module 120, the second vibration-proof pads 536 may be inserted into a gap G between the chamber 110 and the gradient coil module 120 after the gradient coil module 120 is inserted into the chamber 110. The second vibration-proof pads 536 may be inserted in a manner that the second vibration-proof pads 536 are supported by a supporting ring 538. However, the second vibration-proof pads 536 may also be individually inserted without the supporting ring 538. In the gradient coil mounting unit 530 according to the current exemplary embodiment, the elements of the gradient coil mounting unit 530 are substantially the same as those of the gradient coil mounting unit 430, and thus, the description thereof will not be repeated.

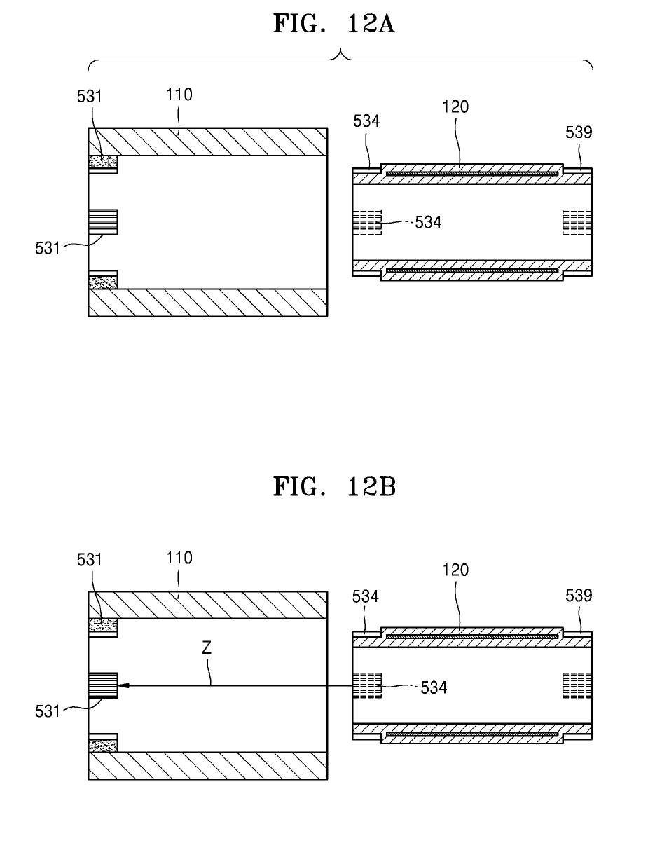

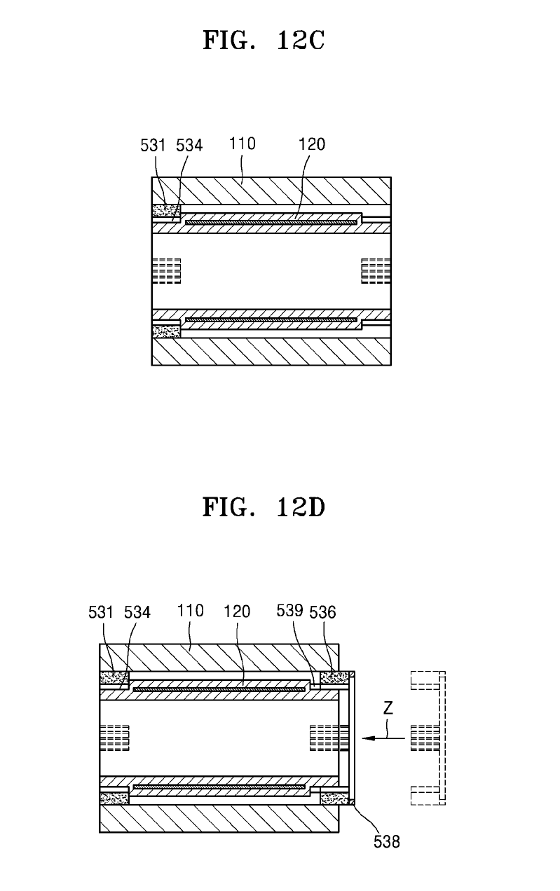

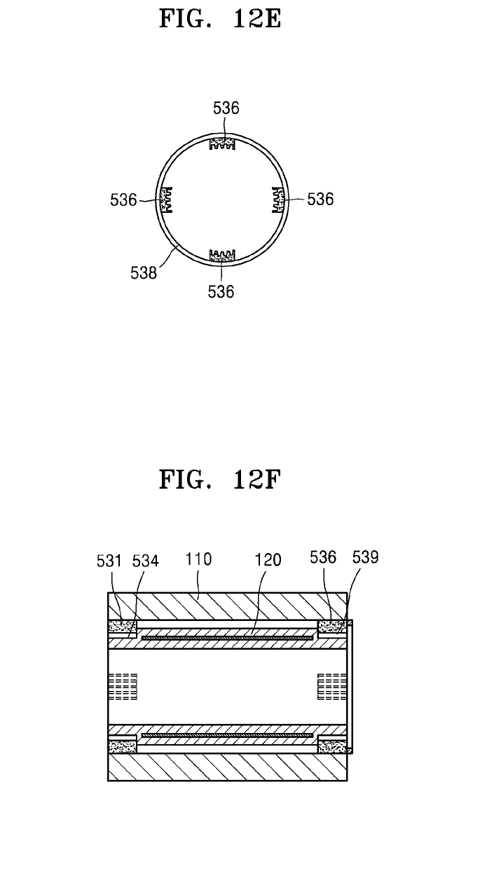

FIGS. 12A, 12B, 12C, 12D, 12E, and 12F are drawings showing a process of mounting a gradient coil module 120 on the MRI apparatus 100 having the gradient coil mounting unit 530 of FIGS. 11A through 11C, according to an exemplary embodiment.

FIG. 12A shows the gradient coil module 120 which is not inserted into the chamber 110. Referring to FIG. 12A, in the gradient coil mounting unit 530 according to the current exemplary embodiment, before the gradient coil module 120 is mounted in the chamber 110, the second vibration-proof pads 536 are not attached to an inner surface of the chamber 110.

As depicted in FIG. 12B, when the gradient coil module 120 is inserted (direction Z) into the chamber 110 with the first fixing taps 534 of the gradient coil module 120 as a front side, the gradient coil module 120 may be smoothly inserted into the chamber 110 until the first fixing taps 534 meet the first vibration-proof pads 531. Next, as depicted in FIG. 12C, after the first fixing taps 534 meet the first vibration-proof pads 531, the gradient coil module 120 is inserted in the direction Z, the first fixing taps 534 and the first vibration-proof pads 531 are geared with each other. Next, as depicted in FIGS. 12D and 12E, the second vibration-proof pads 536 that are separately provided are inserted (direction Z) between the chamber 110 and the gradient coil module 120. Once completed, as depicted in FIG. 12F, the gradient coil module 120 is mounted in the chamber 110.

Although a few exemplary embodiments have been shown and described, it would be appreciated by those skilled in the art that various changes in form and detail may be made in these exemplary embodiments without departing from the spirit and scope of the disclosure, the scope of which is defined by the claims and their equivalents.

What is claimed is:

1. A gradient coil mounting unit for mounting a gradient coil module in a chamber of a magnetic resonance imaging (MRI) apparatus, the gradient coil mounting unit comprising:
vibration-proof pads provided on first and second edges of an inner surface of the chamber, with respect to a mounting direction of the gradient coil module; and
fixing taps provided on first and second edges of an outer surface of the gradient coil module, with respect to the mounting direction,
wherein at least one vibration-proof pad has a shape that is complementary to a shape of a corresponding fixing tap.

2. The gradient coil mounting unit of claim 1, wherein the at least one vibration-proof pad has first screw lines,
the corresponding fixing tap has second screw lines complementary to the first screw lines, and
the gradient coil module is mounted in the chamber by gearing the first screw lines of the at least one vibration-proof pad with the second screw lines of the corresponding fixing tap while the gradient coil module is rotated in the chamber.

3. The gradient coil mounting unit of claim 1, wherein the vibration-proof pads are provided on at least three locations along an inner circumference of the chamber.

4. The gradient coil mounting unit of claim 3, wherein the fixing taps are provided contiguously, without separating gaps therebetween, or discontinuously with the separating gaps therebetween, along an outer circumference of the gradient coil module.

5. The gradient coil mounting unit of claim 1, wherein the vibration-proof pads are provided contiguously, without separating gaps, along an inner circumference of the chamber.

6. The gradient coil mounting unit of claim 5, wherein the fixing taps are provided contiguously, without the separating gaps therebetween, or discontinuously, with the separating gaps therebetween, along an outer circumference of the gradient coil module.

7. The gradient coil mounting unit of claim 1, wherein the at least one vibration-proof pad has a first gear shape in which a protrusion member and a concave member extend in the mounting direction and alternatively repeated,
the corresponding fixing tap has a second gear shape complementary to the first gear shape, and
the gradient coil module is mounted in the chamber by gearing the first gear shape of the at least one vibration-proof pad with the second gear shape of the corresponding fixing tap while the gradient coil module is moved into the chamber, in a straight forward direction substantially parallel to the mounting direction.

8. The gradient coil mounting unit of claim 1, wherein the fixing taps comprise first fixing taps provided on first edge of the outer surface of the gradient coil module and second fixing taps provided on the second edge of the outer surface of the gradient coil module,
the first fixing taps are concavely formed on the outer surface of the gradient coil module, and
the second fixing taps are convexly formed on the outer surface of the gradient coil module.

9. The gradient coil mounting unit of claim 8, wherein the vibration-proof pads comprise first and second vibration-proof pads,
the first vibration-proof pads have thicknesses, in a direction perpendicular to the mounting direction, greater than that of the second vibration-proof pads,
the first vibration-proof pads are geared with the first fixing taps, and
the second vibration-proof pads are geared with the second fixing taps.

10. The gradient coil mounting unit of claim 1, wherein the fixing taps comprise first fixing taps provided on first edge of the outer surface of the gradient coil module and second fixing taps provided on the second edge of the outer surface of the gradient coil module, and
the first and second fixing taps are concavely formed on the outer surface of the gradient coil module.

11. The gradient coil mounting unit of claim 10, wherein the vibration-proof pads comprise first vibration-proof pads provided on the first edge of the inner surface of the chamber that are geared with the first fixing taps and second vibration-proof pads provided on the second edge of the inner surface of the chamber that are geared with the second fixing taps, and
the first and second vibration-proof pads have the same thickness, in a direction perpendicular to the mounting direction.

12. The gradient coil mounting unit of claim 11, wherein the second vibration-proof pads are inserted into a gap between the chamber and the gradient coil module after the gradient coil module is inserted into the chamber.

13. The gradient coil mounting unit of claim 1, wherein the corresponding fixing tap has a tapered shape having a thickness, in a direction perpendicular to the mounting direction, which is gradually increased in a direction from the first edge toward the second edge, of the outer surface of the gradient coil module.

14. The gradient coil mounting unit of claim 1, wherein the corresponding fixing tap has a thickness, in a direction perpendicular to the mounting direction, which is constant in a direction from the first edge toward the second edge, of the outer surface of the gradient coil module.

15. The gradient coil mounting unit of claim 1, wherein the outer surface of the gradient coil module is separated from the inner surface of the chamber by the gradient coil mounting unit.

16. The gradient coil mounting unit of claim 1, wherein the gradient coil module comprises a gradient coil and a resin mold in which the gradient coil is fixed.

17. The gradient coil mounting unit of claim 16, wherein the fixing taps are formed as one body with the resin mold or is attached to the resin mold.

18. A magnetic resonance imaging (MRI) apparatus comprising:
a chamber in which a main magnet is mounted;
a gradient coil module that is mounted in the chamber; and
a gradient coil mounting unit that mounts the gradient coil module in the chamber, and comprises:
vibration-proof pads provided on first and second edges of an inner surface of the chamber, with respect to a mounting direction of the gradient coil module, and
fixing taps which are provided on first and second edges of an outer surface of the gradient coil module, with respect to the mounting direction, and which are shaped complementary to the vibration-proof pads.
